(19) United States
(12) Patent Application Publication
(10) Pub. No.: US 2023/0232647 A1
(43) Pub. Date: Jul. 20, 2023

(54) QUANTUM DOT DISPERSION SOLUTION AND PRODUCTION METHOD FOR ELECTROLUMINESCENT ELEMENT USING SAME

(71) Applicant: Sharp Kabushiki Kaisha, Sakai City, Osaka (JP)

(72) Inventors: Masaki YAMAMOTO, Sakai City (JP); Kazuki GOTO, Sakai City (JP); Yuma YAGUCHI, Sakai City (JP); Soichiro NIKATA, Chikushino-city (JP); Yuko OGURA, Chikushino-city (JP); Masanori TANAKA, Chikushino-city (JP); Yuka TAKAMIZUMA, Chikushino-city (JP); Tetsuji ITO, Chikushino-city (JP); Mikihiro TAKASAKI, Chikushino-city (JP)

(21) Appl. No.: 18/010,828

(22) PCT Filed: Jul. 3, 2020
(86) PCT No.: PCT/JP2020/026184

§ 371 Date: Dec. 16, 2022

(51) Int. Cl. H10K 50/115; C09K 11/88; B82Y 30/00; B82Y 40/00

(52) U.S. Cl. CPC H10K 50/115; B82Y 30/00; B82Y 40/00; C09K 11/881

(57) ABSTRACT

A quantum dot (QD) dispersion solution includes QD phosphor particles, ligands, and a solvent. Each ligand includes a thiol group and at least one functional group of ester groups and ether groups. The solvent is propylene glycol monomethyl ether acetate.

### TECHNICAL FIELD

The disclosure relates to a quantum dot dispersion solution containing quantum dots (quantum dot phosphor particles) and to a method for manufacturing an electroluminescent element in which the quantum dot dispersion solution is used.

### BACKGROUND ART

In recent years, various features related to electroluminescent elements containing quantum dots (quantum dot phosphor particles) have been developed. An example of such electroluminescent element is a quantum dot light-emitting diode (QLED).

A light-emitting layer of the electroluminescent element is formed by applying a quantum dot dispersion solution containing quantum dots (see, for example, Japanese Unexamined Patent Application Publication No. 2013-157180).

### SUMMARY

### Technical Problem

When a light-emitting layer is formed by applying a quantum dot dispersion solution, in order to obtain the desired layer thickness of the light-emitting layer, the quantum dot dispersion solution is diluted such that the concentration of the quantum dots is a desired concentration. However, there is a problem that, after the quantum dot dispersion solution has been diluted, the photoluminescence quantum yield (PLQY) decreases over time.

Therefore, the quantum dot dispersion solution is generally diluted immediately before forming the light-emitting layer. Accordingly, a process of diluting the quantum dot dispersion solution is typically required in a series of processes for manufacturing the electroluminescent element, and therefore the process of diluting the quantum dot dispersion solution is one cause of an increase in the takt time required for manufacturing the electroluminescent element.

In view of the above-mentioned problem, an object of one aspect of the disclosure is to provide a quantum dot dispersion solution that can suppress a decrease in the photoluminescence quantum yield after dilution of the quantum dot dispersion solution in comparison to a known quantum dot dispersion solution. In addition, another object of one aspect of the disclosure is to provide a method for manufacturing an electroluminescent element in which the quantum dot dispersion solution described above is used, the method enabling a reduction in takt time in comparison to known methods.

### Solution to Problem

In order to solve the above problems, a quantum dot dispersion solution according to one aspect of the disclosure includes quantum dots, ligands, and a solvent, each ligand has a thiol group and at least one functional group of an ester group and an ether group, and the solvent is propylene glycol monomethyl ether acetate.

Also, in order to solve the problems described above, a method for manufacturing an electroluminescent element according to one aspect of the disclosure is a method for manufacturing an electroluminescent element provided with a quantum dot light-emitting layer including quantum dots, the manufacturing method including a quantum dot light-emitting layer formation process in which a quantum dot dispersion solution containing quantum dots, ligands, and a solvent is applied to form the quantum dot light-emitting layer, and in the quantum dot light-emitting layer formation process, the quantum dot dispersion solution according to one aspect of the disclosure is used as the quantum dot dispersion solution.

### Advantageous Effects of Disclosure

According to one aspect of the disclosure, a quantum dot dispersion solution can be provided which can suppress a decrease in the photoluminescence quantum yield after dilution of the quantum dot dispersion solution in comparison to known quantum dot dispersion solutions, can be stored in a diluted state, and can reduce the takt time required for manufacturing the electroluminescent element in comparison to known quantum dot dispersion solutions. In addition, according to one aspect of the disclosure, a method for manufacturing an electroluminescent element using the quantum dot dispersion solution described above can be provided, the method enabling a reduction in the takt time in comparison to known methods.

### BRIEF DESCRIPTION OF DRAWINGS

FIG. 1 is a cross-sectional view schematically illustrating an overall configuration of an electroluminescent element according to a first embodiment.

FIG. 2 is a schematic view illustrating an example of a quantum dot dispersion solution according to the first embodiment.

FIG. 3 is a flowchart illustrating an example of a method for manufacturing the electroluminescent element according to the first embodiment.

FIG. 4 is a cross-sectional view schematically illustrating an overall configuration of main portions of a display device according to a second embodiment.

FIG. 5 is a diagram for illustrating a modified example of the display device according to the second embodiment.

FIG. 6 is a diagram for illustrating another modified example of the display device according to the second embodiment.

FIG. 7 is a diagram for illustrating a display device according to a third embodiment.

FIG. 8 is a diagram for illustrating a modified example of the display device according to the third embodiment.

### DESCRIPTION OF EMBODIMENTS

### First Embodiment

An electroluminescent element that emits light when a voltage is applied to quantum dot phosphor particles (quantum dot: QD, also referred to as semiconductor nanoparticle phosphors) is provided with a quantum dot light-emitting layer containing quantum dot phosphor particles. Such a quantum dot light-emitting layer is prepared by applying a quantum dot dispersion solution containing quantum dot phosphor particles onto an underlayer thereof.

Note that hereinafter, in the disclosure, a quantum dot phosphor particle is abbreviated as a “QD phosphor particle”. In addition, a QD phosphor particle may also be referred to simply as a “quantum dot” or a “QD”. Also, a description of “from A to B” for two numbers A and B is intended to mean “equal to or greater than A and equal to or less than B”, unless otherwise specified.

Before describing a quantum dot dispersion solution according to the present embodiment, an electroluminescent element in which the quantum dot dispersion solution is used will be first described.

### Structural Example of Electroluminescent Element

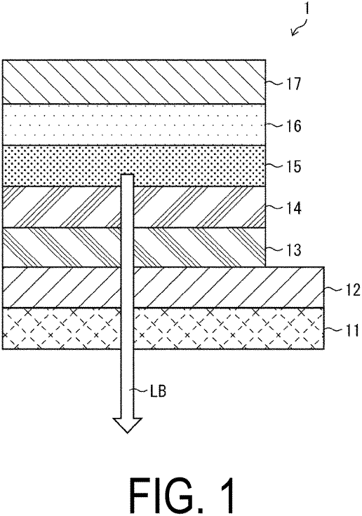

FIG. 1 is a cross-sectional view schematically illustrating an overall configuration of an electroluminescent element 1 according to the present embodiment.

The electroluminescent element 1 illustrated in FIG. 1 is an element that emits light when a voltage is applied to the QD phosphor particles. Examples of the electroluminescent element 1 include a quantum dot light-emitting diode (QLED). In the present embodiment, the QD phosphor particles contained in the electroluminescent element 1 are blue QD phosphor particles.

The electroluminescent element 1 includes an anode electrode 12 (anode, first electrode), a cathode electrode 17 (cathode, second electrode), and a function layer provided between the anode electrode 12 and the cathode electrode 17. The function layer includes at least a QD layer 15 (quantum dot light-emitting layer, blue quantum dot light-emitting layer) containing QD phosphor particles. Note that in the present embodiment, the layers between the anode electrode 12 and the cathode electrode 17 are collectively referred to as a function layer.

The function layer may be a single layer type formed only of the QD layer 15, or may be a multi-layer type including a function layer in addition to the QD layer 15. Of the function layer, examples of function layers besides the QD layer 15 include a hole injection layer 13 (HIL), a hole transport layer 14 (HTL), and an electron transport layer 16 (ETL).

Note that in the disclosure, a direction from an anode electrode 12 to a cathode electrode 17 in FIG. 1 is referred to as an upward direction, and the opposite direction thereof is referred to as a downward direction. In the disclosure, a horizontal direction is a direction (a main surface direction of each portion included in the electroluminescent element 1) perpendicular to a vertical direction. The vertical direction can also be referred to as a normal direction of each portion described above.

Each layer from the anode electrode 12 to the cathode electrode 17 is generally formed on a substrate used as a support body. Accordingly, the electroluminescent element 1 may be provided with a substrate as a support body.

As one example, the electroluminescent element 1 illustrated in FIG. 1 has a configuration in which a substrate 11, the anode electrode 12, the hole injection layer 13, the hole transport layer 14, the QD layer 15, the electron transport layer 16, and the cathode electrode 17 are layered in this order towards the upward direction of FIG. 1.

However, the configuration of the electroluminescent element 1 is not limited to the above configuration, and the electroluminescent element 1 may have a configuration in which the cathode electrode 17, the electron transport layer 16, the QD layer 15, the hole transport layer 14, the hole injection layer 13, and the anode electrode 12 are layered, in this order, on the substrate 11.

Thus, the QD layer 15 is interposed between the anode electrode 12 and the cathode electrode 17. In other words, the anode electrode 12 and the cathode electrode 17 are provided so as to sandwich the QD layer 15. Note that the electroluminescent element 1 may further include an electron injection layer between the QD layer 15 and the cathode electrode 17. For example, when the electroluminescent element 1 includes an electron transport layer 16 as illustrated in FIG. 1, the electroluminescent element 1 may include an electron injection layer between the electron transport layer 16 and the cathode electrode 17.

Hereinafter, each layer described above will be described in greater detail.

The substrate 11 is a support body for forming each layer from the anode electrode 12 to the cathode electrode 17, as described above. As illustrated in FIG. 1, the substrate 11 supports, thereon or thereabove, the anode electrode 12, the hole injection layer 13, the hole transport layer 14, the QD layer 15, the electron transport layer 16, and the cathode electrode 17.

The substrate 11 may be, for example, a glass substrate, or may be a flexible substrate such as a plastic substrate.

The electroluminescent element 1 may be used, for example, as a light source of an electronic device such as a display device. When the electroluminescent element 1 is part of a display device, for example, a substrate of the display device is used as the substrate 11. Thus, the electroluminescent element 1 may be referred to as an electroluminescent element 1 including the substrate 11, or may be referred to as an electroluminescent element 1 not including the substrate 11.

In this manner, the electroluminescent element 1 may itself include a substrate 11, or the substrate 11 of the electroluminescent element 1 may be a substrate of an electronic device such as a display device provided with the electroluminescent element 1. When the electroluminescent element 1 is part of a display device, for example, an array substrate on which a plurality of thin film transistors are formed may be used as the substrate 11. In this case, the anode electrode 12, which is a first electrode provided on the substrate 11, may be electrically connected to the thin film transistors of the array substrate.

In the case where the electroluminescent element 1 is, for example, part of a display device in this manner, the electroluminescent element 1 is provided as a light source on the substrate 11 for each pixel. Specifically, a red pixel (R pixel) is provided with, as a red light source, an electroluminescent element (red electroluminescent element) that emits red light. A green pixel (G pixel) is provided with, as a green light source, an electroluminescent element (green electroluminescent element) that emits green light. A blue pixel (B pixel) is provided with, as a blue light source, an electroluminescent element (blue electroluminescent element) that emits blue light. Accordingly, banks partitioning each pixel may be formed as pixel separation films such that electroluminescent elements can be formed on the substrate 11 for each R pixel, G pixel, and B pixel.

In the present embodiment, as described above, a case is described in which the electroluminescent element 1 illustrated in FIG. 1 is a blue electroluminescent element in which a QD layer 15 including blue quantum dots (blue QD phosphor particles) is used. However, the abovementioned red electroluminescent element is enabled by providing a QD layer containing red quantum dots (red QD phosphor particles) as the QD layer 15. Similarly, the abovementioned green electroluminescent element is enabled by providing a QD layer containing green quantum dots (green QD phosphor particles) as the QD layer 15.

In a bottom-emitting (BE) type electroluminescent element, light emitted from the QD layer 15 is emitted downward (i.e., towards the substrate 11 side). In a top-emitting (TE) type electroluminescent element, light emitted from the QD layer 15 is emitted upward (i.e., towards the side opposite the substrate 11). In a double-sided electroluminescent element, the light emitted from the QD layer 15 is emitted downward and upward.

In a case where the electroluminescent element 1 is a bottom emission (BE) type electroluminescent element or a double-sided electroluminescent element, the substrate 11 is constituted of a light-transmissive substrate made of a light-transmissive material. In a case where the electroluminescent element 1 is a top-emitting (TE) type electroluminescent element, the substrate 11 may be constituted of a light-transmissive material, or may be constituted of a light-reflective material.

Of the anode electrode 12 and the cathode electrode 17, the electrode serving as the light extraction surface side must be light-transmissive. Also note that the electrode of the side opposite the light extraction surface may or may not be light-transmissive.

For example, when the electroluminescent element 1 is a BE-type electroluminescent element, the electrode on the upper-layer side is a light-reflective electrode, and the electrode on the lower-layer side is a light-transmissive electrode. When the electroluminescent element 1 is a TE-type electroluminescent element, the electrode of the upper-layer side is a light-transmissive electrode, and the electrode of the lower-layer side is a light-reflective electrode. Note that the light-reflective electrode may be a layered body of a layer formed of a light-transmissive material and a layer formed of a light-reflective material.

In FIG. 1, as one example, a case is illustrated in which the electroluminescent element 1 is a BE-type electroluminescent element in which the anode electrode 12 is used as the electrode of the lower-layer side, the cathode electrode 17 is used as the electrode of the upper-layer side, and blue light LB emitted from the QD layer 15 is emitted downward. Therefore, a light-transmissive electrode is used as the anode electrode 12 such that the blue light LB emitted from the QD layer 15 can be transmitted through the anode electrode 12. A light-reflective electrode is used as the cathode electrode 17 such that the blue light LB emitted from the QD layer 15 is reflected. Note that in the following description, the “blue light LB” is also abbreviated simply as “LB”. Other members will be similarly abbreviated as appropriate.

The anode electrode 12 is an electrode that supplies positive holes (holes) to the QD layer 15 when a voltage is applied. The anode electrode 12 includes for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 17 is an electrode that supplies electrons to the QD layer 15 when a voltage is applied to the cathode electrode 17. The cathode electrode 17 includes, for example, a material having a relatively small work function. Examples of the material include Al, silver (Ag), Ba, ytterbium (Yb), calcium (Ca), lithium (Li)-Al alloys, Mg-Al alloys, Mg-Ag alloys, Mg-indium (In) alloys, and Al-aluminum oxide (Al₂O₃) alloys.

Film formation of the anode electrode 12 and the cathode electrode 17 may be implemented using, for example, sputtering, film evaporation, film vapor deposition, vacuum vapor deposition, or physical vapor deposition (PVD).

The hole injection layer 13 is a layer that transports positive holes supplied from the anode electrode 12, to the hole transport layer 14. The hole injection layer 13 may be formed of an organic material or may be formed of an inorganic material. An example of the organic material is an electrically conductive polymer material. As the polymer material, for example, a composite (PEDOT:PSS) of poly(3,4-ethylenedioxythiophene) (PEDOT), poly(3,4-ethylenedioxythiophene) (PEDOT) and polystyrene sulfonic acid (PSS) can be used.

The hole transport layer 14 is a layer that transports positive holes supplied from the hole injection layer 13, to the QD layer 15. The hole transport layer 14 may be formed of an organic material or may be formed of an inorganic material. An example of the organic material is an electrically conductive polymer material. As the polymer material, for example, poly [(9,9-dioctylfluorenyl-2,7-diyl)-co-(4,4′-(N-(4-sec-butylphenyl) diphenylamine))] (TFB) can be used. A single type of these polymer materials may be used alone, or two or more types may be mixed and used, as appropriate. In addition, the hole transport layer 14 is preferably formed to have a layer thickness within a range from 10 nm to 57 nm. This allows an even higher EQE to be obtained.

In the film formation of the hole injection layer 13 and the hole transport layer 14, for example, sputtering, vacuum vapor deposition, PVD, spin coating, or an ink-jet method may be used. Note that in a case where positive holes can be sufficiently supplied to the QD layer 15 only by the hole transport layer 14, the hole injection layer 13 need not be provided.

The electron transport layer 16 is a layer that transports electrons supplied from the cathode electrode 17, to the QD layer 15. The electron transport layer 16 may be formed of an organic material or may be formed of an inorganic material. When the electron transport layer 16 is formed of an inorganic material, the electron transport layer 16 may contain, as the inorganic material, a metal oxide containing at least one element selected from the group consisting of Zn, magnesium (Mg), titanium (Ti), silicon (Si), tin (Sn), tungsten (W), tantalum (Ta), barium (Ba), zirconium (Zr), aluminum (Al), yttrium (Y), and hafnium (Hf). Examples of such metal oxides include zinc oxide (ZnO) and zinc magnesium oxide (ZnMgO). A single type of these metal oxides may be used alone, or two or more types may be mixed and used, as appropriate. Also, nanoparticles may be used in the inorganic material. Of the abovementioned inorganic materials, the electron transport layer 16 preferably contains ZnMgO. This allows an even higher external quantum efficiency (EQE) to be obtained. When the electron transport layer 16 is an inorganic material, spin coating or an ink-jet method, for example, can be used for film formation of the electron transport layer 16.

If the electron transport layer 16 is formed of an organic material, the electron transport layer 16 preferably contains, as the organic material, at least one type of compound selected from the group consisting of (i) 1,3,5-tris(1-phenyl-1H-benzimidazol-2-yl)benzene (TPBi), (ii) 3-(biphenyl-4-yl)-5-(4-tert-butylphenyl)-4-phenyl-4H-1,2,4-triazole (TAZ), (iii) bathophenanthroline (Bphen), and (iv) tris(2,4,6-trimethyl-3-(pyridin-3-yl)phenyl)borane (3TPYMB). If the electron transport layer 16 is formed of an organic material, film formation of the electron transport layer 16 may be implemented using vacuum vapor deposition. In addition, as in the case in which the material is an inorganic material, when the material is an organic material, spin coating or an ink-jet method may be used for film formation of the electron transport layer 16.

The QD layer 15 is a light-emitting layer (QD phosphor particle layer) that is provided between the anode electrode 12 and the cathode electrode 17 and contains the QD phosphor particles (quantum dots) and ligands, which are coordinated on the surface of the QD phosphor particles and protect the surface of the QD phosphor particle. The amount of ligands in the QD layer 15 is adjusted such that a weight ratio of the ligands to the QD phosphor particles (ligands/QD phosphor particles) is in a range from 0.01 times to 2 times.

The QD phosphor particles emit the LB in association with recombination of the positive holes supplied from the anode electrode 12 and the electrons (free electrons) supplied from the cathode electrode 17. That is, the QD layer 15 emits light through electroluminescence (EL). More specifically, the QD layer 15 emits light through injection type EL.

The QD layer 15 is formed by a solution method in which a dispersion solution (quantum dot dispersion solution, liquid composition) obtained by dispersing QD phosphor particles and ligands in a dispersion medium is applied onto the underlayer (on the hole transport layer 14 in the example illustrated in FIG. 1.). The above dispersion solution (hereinafter, referred to as a “QD dispersion solution”) will be described later in detail together with the description of the QD phosphor particles and ligands.

The QD layer 15 is preferably formed such that the layer thickness is, for example, from 15 nm to 35 nm. This allows an even higher EQE to be obtained.

In the electroluminescent element 1, a forward voltage is applied between the anode electrode 12 and the cathode electrode 17. In other words, the anode electrode 12 is set to a higher potential than the cathode electrode 17. Through this, (i) electrons can be supplied from the cathode electrode 17 to the QD layer 15, and (ii) positive holes can be supplied from the anode electrode 12 to the QD layer 15. As a result, the QD layer 15 can generate the LB in association with the recombination of the positive holes and the electrons. The above-described application of voltage may be controlled by a thin film transistor (TFT) (not illustrated). As an example, a TFT layer including a plurality of TFTs may be formed in the substrate 11.

Note that the electroluminescent element 1 may include, as a function layer, a hole blocking layer (HBL) that suppresses the transport of positive holes. The hole blocking layer is provided between the anode electrode 12 and the QD layer 15. By providing the hole blocking layer, the balance of the carriers (i.e., positive holes and electrons) supplied to the QD layer 15 can be adjusted.

In addition, the electroluminescent element 1 may include, as a function layer, an electron blocking layer (EBL) that suppresses the transport of electrons. The electron blocking layer is provided between the QD layer 15 and the cathode electrode 17. By providing the electron blocking layer, the balance of the carriers (i.e., positive holes and electrons) supplied to the QD layer 15 can also be adjusted.

The electroluminescent element 1 may be sealed after film formation as far as the cathode electrode 17 has been completed. For example, a glass or a plastic can be used as a sealing member. The sealing member has, for example, a concave shape so that a layered body from the substrate 11 to the cathode electrode 17 can be sealed. For example, after a sealing adhesive (e.g., an epoxy-based adhesive) is applied between the sealing member and the substrate 11, sealing is implemented in a nitrogen (N₂) atmosphere, and thereby the electroluminescent element 1 is manufactured.

### Application in Display Device

As described above, the electroluminescent element 1 may be adopted, for example, as a blue light source of a display device. The light source including the electroluminescent element 1 may include an electroluminescent element as a red light source and an electroluminescent element as a green light source. In this case, the light source functions as, for example, a light source for lighting an R pixel, a G pixel, and a B pixel, as indicated in a below-described second embodiment. The display device including this light source can express an image by a plurality of pixels including the R pixel, the G pixel, and the B pixel.

For example, the R pixel, the G pixel, and the B pixel are each formed by using an ink-jet method or the like for separate application on the substrate 11 provided with a bank. For example, indium phosphide (InP) is suitably used as the red QD phosphor particles and the green QD phosphor particles used for the R pixel and G pixel respectively, as long as the materials are limited to non-Cd-based materials. When InP is used, the fluorescence full-width at half-maximum can be made relatively narrow, and high luminous efficiency can be obtained.

Film formation of the electron transport layer 16 may be implemented with a plurality of pixel units or may be implemented in common for the plurality of pixels, provided that the display device can light up the R pixel, G pixel, and B pixel individually.

### QD Dispersion Solution

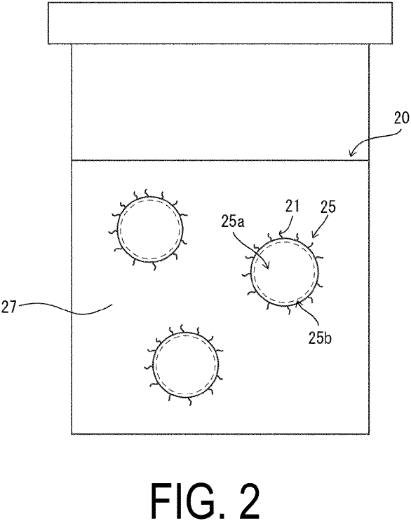

FIG. 2 is a schematic view illustrating an example of a QD dispersion solution 20 (quantum dot dispersion solution, liquid composition) according to the present embodiment.

As illustrated in FIG. 2, the QD dispersion solution 20 contains QD phosphor particles 25, ligands 21, and a solvent 27 (organic solvent) as a dispersion medium. The QD dispersion solution 20 is a so-called colloidal solution in which the QD phosphor particles 25 and ligands 21 are dispersed (also referred to as “dissolved”) in the solvent 27.

Numerous ligands 21 are coordinated (adsorbed) on the surface of each of the QD phosphor particles 25, as illustrated in FIG. 2. By coordinating the ligands 21 on the surfaces of the QD phosphor particles 25, mutual aggregation of QD phosphor particles 25 can be suppressed, and thus target optical characteristics are easily exhibited.

Of a core 25a and a shell 25b covering the surface of the core 25a, the QD phosphor particle 25 includes at least the core 25a. Note that in FIG. 2, an example is illustrated in which the QD phosphor particle 25 has a core-shell structure including the core 25a and the shell 25b covering the surface of the core 25a.

However, as described above, the QD phosphor particle 25 may include only the core 25a. Even when the QD phosphor particle 25 is formed of only the core 25a, the QD phosphor particle 25 emits fluorescence as LB in association with the recombination of positive holes and electrons. The shell 25b may be formed in a state of being solid-solved on the surface of the core 25a. In FIG. 2, the boundary between the core 25a and the shell 25b is indicated by a dotted line, and this indicates that the boundary between the core 25a and the shell 25b may or may not be confirmed by analysis.

The QD phosphor particles 25 according to the present embodiment are nanocrystals not containing cadmium (Cd). In the disclosure, the term “nanocrystal” indicates a nanoparticle having an approximate particle size from several nm to several tens of nm.

As the QD phosphor particle 25, a Cd-free QD phosphor particle having a core containing at least zinc (Zn) and selenium (Se) and not containing cadmium (Cd) is used. Note that in the disclosure, “not containing Cd” means that the QD phosphor particle 25 does not contain Cd at a mass ratio of 1/30 or greater in relation to Zn. Therefore, if the QD phosphor particles 25 have a core-shell structure as described above, “not containing Cd” means that the core 25a and the shell 25b both do not contain Cd at a mass ratio of 1/30 or greater in relation to Zn.

The QD phosphor particles 25 are preferably nanocrystals containing Zn and Se, Zn, Se and sulfur (S), Zn, Se and tellurium (Te), or Zn, Se, Te and S. Specifically, ZnSe-based, ZnSeS-based, ZnSeTe-based, or ZnSeTeS-based QD phosphor particles are used as the QD phosphor particles 25.

The core 25a is formed of, for example, ZnSe, ZnSeS, ZnSeTe, or ZnSeTeS. Among these exemplary materials, the material of the core 25a is preferably ZnSe or ZnSeS, and more preferably ZnSe.

The material of the shell 25b may be any material as long as the material does not contain Cd, and for example, the shell 25b may be formed of ZnS or ZnSeS. Among these exemplary materials, the material of the shell 25b is preferably ZnS.

According to the present embodiment, the photoluminescence quantum yield (PLQY) can be further increased by covering the core 25a formed of a nanocrystal such as ZnSe, ZnSeS, ZnSeTe, or ZnSeTeS with a shell 25b such as ZnS or ZnSeS in this manner.

Note that the Zn and Se, the Zn, Se and S, the Zn, Se and Te, or the Zn, Se, Te and S included in QD phosphor particles 25 are the main components. The QD phosphor particles 25 may include elements besides these elements.

However, the QD phosphor particles 25 preferably do not contain Cd and do not contain phosphorus (P). Organic phosphorus compounds are expensive. Furthermore, organic phosphorus compounds are easily oxidized in air, and therefore a variety of problems are likely to occur such as unstable synthesis, an increase in costs, unstable fluorescence characteristics, and an increase in the complexity of the manufacturing process.

The QD phosphor particles 25 have fluorescence characteristics due to band-end light emission, and a quantum size effect occurs due to the particles being of a nano size.

A peak wavelength of the QD phosphor particles 25 depends on subtle difference among the compositional ratios of the constituent elements of the QD phosphor particles 25, and the relationship between the particle size and the magnitude of wavelength dependence varies depending on the particle size region. However, regardless of whether the QD phosphor particles 25 have a core-shell structure, the particle size of the QD phosphor particles 25 is preferably in a range from 3 nm to 20 nm. Furthermore, the particle size of the QD phosphor particles 25 is more preferably within a range from 5 nm to 20 nm, regardless of whether the QD phosphor particles 25 have a core-shell structure. Moreover, the particle size of the QD phosphor particles 25 is more preferably 15 nm or less, and even more preferably 10 nm or less. In the present embodiment, the particle size of the QD phosphor particles 25 can be adjusted within the range described above, and a large number of QD phosphor particles 25 can be produced with a substantially uniform particle size.

Note that when the QD phosphor particles 25 have a core-shell structure, the particle size of the QD phosphor particles 25 indicates the particle size of the QD phosphor particles 25 in a state of being covered by the shell 25b (that is, the outermost particle size of the QD phosphor particles 25). According to the present embodiment, the QD phosphor particles 25 have a core-shell structure, and thus while the particle size is slightly larger than the structure of the core 25a alone, the particle size of the QD phosphor particles 25 can be maintained at 20 nm or less. In this manner, according to the present embodiment, QD phosphor particles 25 having a core-shell structure made uniform with a very small particle size can be obtained.

In the present embodiment, as described above, the particle size of the QD phosphor particles 25 can be reduced, and variations in the particle size of each QD phosphor particle 25 can be reduced, and thus QD phosphor particles 25 having uniform size can be obtained.

Accordingly, in the present embodiment, the fluorescence full-width at half-maximum of the QD phosphor particles 25 can be narrowed to 25 nm or less, and the formation of a high-color gamut can be improved. Note that the “fluorescence full-width at half-maximum” is a full width at half maximum (FWHM), which indicates the spread of fluorescence wavelengths at half the intensity of a peak value of a fluorescence intensity in a fluorescent spectrum.

Additionally, the fluorescence full-width at half-maximum is preferably 23 nm or smaller, more preferably 20 nm or smaller, and even more preferably 15 nm or smaller. In the present embodiment, the fluorescence full-width at half-maximum can be narrowed in this manner, and thus the formation of a high color gamut can be improved.

In particular, the QD phosphor particles 25 according to the present embodiment are synthesized by synthesizing a copper chalcogenide as a precursor from a copper (Cu) raw material and an organic chalcogen compound (organic chalcogenide) as an Se raw material or a Te raw material, and then subjecting to a metal exchange of Cu of the copper chalcogenide with Zn. Note that an organic copper compound or an inorganic copper compound is used for the Cu raw material.

According to the present embodiment, synthesis can be safely implemented by synthesizing the QD phosphor particles 25 on the basis of an indirect synthesis reaction using these types of materials having relatively high stability (materials with relatively low reactivity), and as described above, QD phosphor particles 25 having a uniform size can be obtained. As a result, the fluorescence full-width at half-maximum can be narrowed, and a fluorescence full-width at half-maximum of 25 nm or less can be achieved as described above.

In addition, according to the present embodiment, the fluorescence lifetime of the QD phosphor particles 25 can be set to 50 ns or less. Note that in the disclosure, “fluorescence lifetime” indicates the “time until the initial intensity becomes 1/e (approximately 37%)”.

In addition, in the present embodiment, the fluorescence lifetime can be adjusted to 40 ns or less, and even 30 ns or less. In the present embodiment, the fluorescence lifetime can be shortened in this manner, but can also be extended to approximately 50 ns, and thus the fluorescence lifetime can be adjusted according to the usage application.

In the present embodiment, the fluorescence wavelength can be freely controlled to an approximate range from 410 nm to 470 nm. The fluorescent peak wavelength of the QD phosphor particles 25 is within a range from 410 nm to 470 nm. According to the present embodiment, the fluorescence wavelength can be controlled by adjusting the particle size and composition of the QD phosphor particles 25. The QD phosphor particles 25 are, for example, ZnSe-based or ZnSeS-based solid solution bodies in which a chalcogen element is used in addition to Zn. In this case, the fluorescence wavelength can be preferably set in a range from 430 nm to 470 nm, and more preferably in a range from 450 nm to 470 nm. Furthermore, in the ZnSeTe-based or ZnSeTeS-based QD phosphor particles 25, the fluorescence wavelength can be set to within a range from 450 nm to 470 nm. In this manner, the fluorescence wavelength of the QD phosphor particles 25 can be controlled to blue in the present embodiment.

In the present embodiment, even when the QD phosphor particles 25 have a core-shell structure, the fluorescence wavelength can be freely controlled to an approximate range from 410 nm to 470 nm. That is, according to the present embodiment, the fluorescence wavelength can be controlled to blue even when the QD phosphor particles 25 have a core-shell structure.

In addition, in the present embodiment, even when the QD phosphor particles 25 have a core-shell structure, the fluorescence full-width at half-maximum and the fluorescence lifetime described above can be obtained. In particular, according to the present embodiment, the fluorescence lifetime can be further shortened by adopting a core-shell structure for the QD phosphor particles 25 in comparison to a core 25a alone having the same composition and particle size. Note that the above-described ranges can be applied as preferable ranges of the fluorescence full-width at half-maximum and fluorescence lifetime, even when the QD phosphor particles 25 have a core-shell structure.

Furthermore, in comparison to a case of the core 25a alone, the fluorescent peak wavelength can be shortened or lengthened by covering the core 25a with the shell 25b. For example, when the particle size of the core 25a is small, the fluorescent peak wavelength tends to be lengthened by covering the core 25a with the shell 25b. On the other hand, when the particle size of the core 25a is large, the fluorescent peak wavelength tends to be shortened by covering the core 25a with the shell 25b. Note that the magnitude of change in the wavelength varies depending on the conditions of covering with the shell 25b.

The thickness (shell thickness) of the shell 25b is one of the most important factors determining the efficiency and reliability of the electroluminescent element 1 (QLED). In order to obtain better light emission performance, it is desirable that the QD phosphor particles 25 have a core-shell structure. When the shell thickness is too thick, the photoluminescence quantum yield (PLQY) decreases.

When the QD phosphor particles 25 have a core-shell structure, as described above, the outermost particle size of the QD phosphor particle 25 including the shell 25b is from 3 nm to 20 nm, and is more preferably from 5 nm to 20 nm.

According to the disclosure, in a case in which the QD phosphor particles 25 are formed of only the core 25a, a fluorescence wavelength of 50 ns or less and a high photoluminescence quantum yield (PLQY) can be obtained by setting the thickness of the shell 25b to less than 10 nm. The external quantum efficiency (%) is expressed by (carrier balancing) × (generation efficiency of luminescent excitons) × (photoluminescence quantum yield) × (light extraction efficiency) and is proportional to the photoluminescence quantum yield. Therefore, an electroluminescent element 1 that can realize a high external quantum efficiency (EQE) can be provided by setting the thickness of the shell 25b to less than 10 nm.

Note that when the QD phosphor particles 25 have a core-shell structure, the thickness of the shell 25b is more preferably 0.3 nm or greater, even more preferably 0.5 nm or greater, yet even more preferably 0.8 nm or greater, and even further preferably 1.0 nm or greater. Furthermore, the thickness of the shell 25b is more preferably 3.3 nm or less, even more preferably 2.8 nm or less, and yet even more preferably 1.7 nm or less.

Note that with the core-shell type QD phosphor particles 25, the wavelength of the light emitted by the QD phosphor particles 25 is proportional to the particle size of the core 25a and does not depend on the particle size of the shell 25b (the outermost particle size of the QD phosphor particles 25). Here, the core size is calculated by (core size) = (outermost particle size) - (shell thickness) × 2 and is not particularly limited as long as blue light is emitted. However, the core size is preferably in the range of, for example, from 0.5 nm to 15 nm.

The ligand 21 is a surface-modifying group (organic ligand) that modifies the surface of the QD phosphor particle 25. The ligand 21 used in the present embodiment is a thiol-based ligand having a thiol group and at least one functional group selected from ester groups and ether groups. The thiol group (also referred to as a mercapto group) is a functional group that is coordinated on the surface of the quantum dot.

Examples of the ligand 21 include compounds represented by the following general formula (1).

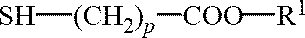

Note that in general formula (1) above, R¹ represents a —[(CH₂)_{q}O]ᵣ—R² group which may have a substituent, p represents an integer from 1 to 15, q represents an integer from 1 to 5, and r represents an integer from 1 to 15. In other words, in general formula (1), R¹ represents a —[(CH₂)_{q}O]ᵣ—R² group that may be unsubstituted or may have a substituent. Furthermore, R² represents a hydrogen atom or an alkyl group having from 1 to 6 carbons.

Note that “may have a substituent” includes both a case in which a hydrogen atom (—H) is substituted by a monovalent group and a case in which a methylene group (—CH₂—) is substituted by a divalent group.

Examples of the substituent group include at least one type of group selected from the group consisting of alkyl groups having from 1 to 10 carbons and ether groups.

The R¹ may be a linear —[(CH₂)_{q}O]ᵣ—R² group, or may be a branched —[(CH₂)_{q}O]ᵣ—R² group.

Examples of the ligand 21 expressed by general formula (1) above include compounds expressed by the following general formula (2).

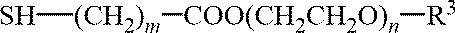

Note that in general formula (2) above, m represents an integer from 5 to 11, n represents an integer from 1 to 10, and R³ represents an alkyl group having from 1 to 6 carbons.

The compound represented by general formula (2) above is a compound for which, in general formula (1), p = m, and R¹ is an unsubstituted or substituted (CH₂CH₂O)ₙ—R³ group. That is, the compound represented by general formula (2) is a compound for which, in general formula (1), R¹ is an unsubstituted or substituted —[(CH₂)_{q}O]ᵣ—R² group, R² is an alkyl group having from 1 to 6 carbons, p is an integer from 5 to 11, q is 2, and r is an integer from 1 to 10.

Examples of the ligand 21 represented by general formula (2) above include compounds represented by the following structural formula (3) (the following rational formula).

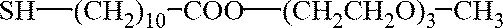

The compound represented by structural formula (3) above is a compound in which, in general formula (2) above, the number of repeating units represented by m is 10, the number of repeating units represented by n is 3, and R³ is a methyl group with one carbon.

Furthermore, the ligand 21 represented by general formula (2) above may be, for example, a compound represented by the following structural formula (4) (the following rational formula).

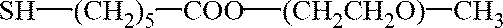

The compound represented by structural formula (4) above is a compound in which, in general formula (2) above, the number of repeating units represented by m is 5, the number of repeating units represented by n is 1, and R³ is a methyl group with one carbon.

The solvent 27 is a dispersion medium in which QD phosphor particles 25 and ligands 21 are dispersed. The solvent 27 used in the QD dispersion solution 20 is propylene glycol monomethyl ether acetate (PGMEA).

The QD layer 15 according to the present embodiment is formed by applying the QD dispersion solution 20 in which the QD phosphor particles 25 and ligands 21 are dispersed in PGMEA. The QD layer 15 formed in this manner by the solution method contains spherical QD phosphor particles 25 and ligands 21 coordinated on the surfaces of the QD phosphor particles 25.

According to the present embodiment, as described above, a thiol-based ligand having a thiol group and at least one functional group of ester groups and ether groups is used as the ligand 21, and PGMEA is used as the solvent 27. Through this, a reduction in the photoluminescence quantum yield (PLQY) over time after dilution of the QD dispersion solution 20 can be suppressed as compared to the known quantum dot dispersion solutions.

Therefore, according to the present embodiment, a QD dispersion solution 20 that can be stored in a state of being diluted in advance to a desired concentration can be provided. Thus, when the QD dispersion solution 20 is used, diluting the QD dispersion solution 20 immediately before forming the QD layer 15 is not necessary. In other words, it is not necessary to dilute the QD dispersion solution 20 immediately prior to use (i.e., application) of the QD dispersion solution 20 when manufacturing the electroluminescent element 1. Therefore, the takt time for manufacturing the electroluminescent element 1 can be improved (reduced).

In the present embodiment, the concentration of QD phosphor particles 25 in the QD dispersion solution 20 is preferably within a range from 0.2 mg/mL to 100 mg/mL. Furthermore, a weight ratio of the ligands 21 to the QD phosphor particles 25 (ligand/QD phosphor particle) is preferably within a range from 0.01 times to 2 times, as described above.

According to the present embodiment, even if the QD dispersion solution 20 is diluted to the concentration described above, a reduction in the photoluminescence quantum yield (PLQY) over time after dilution of the QD dispersion solution 20 can be suppressed as compared to the known quantum dot dispersion solutions. In this manner, according to the present embodiment, a QD dispersion solution 20 that can be stored in a state of being diluted in advance to the concentration described above can be provided.

### Method for Manufacturing Electroluminescent Element

Next, an example of a method for manufacturing the electroluminescent element 1 will be described.

In the method for manufacturing the electroluminescent element 1 according to the present embodiment, as described above, the QD layer 15 is formed by applying the QD dispersion solution 20 obtained by dispersing the QD phosphor particles 25 and the ligands 21 in the solvent 27. Furthermore, as described above, a thiol-based ligand having a thiol group as a functional group that is coordinated on the surface of the QD phosphor particle 25 and at least one functional group of ester groups and ether groups is used as the ligand 21. PGMEA is used as the solvent 27. The method for manufacturing the electroluminescent element 1 according to the present embodiment is not particularly limited.

As one example of a method for manufacturing the electroluminescent element 1, the electroluminescent element 1 is manufactured, for example, by forming, on the substrate 11, the anode electrode 12, the hole injection layer 13, the hole transport layer 14, the QD layer 15, the electron transport layer 16, and the cathode electrode 17 in this order as illustrated in FIG. 1.

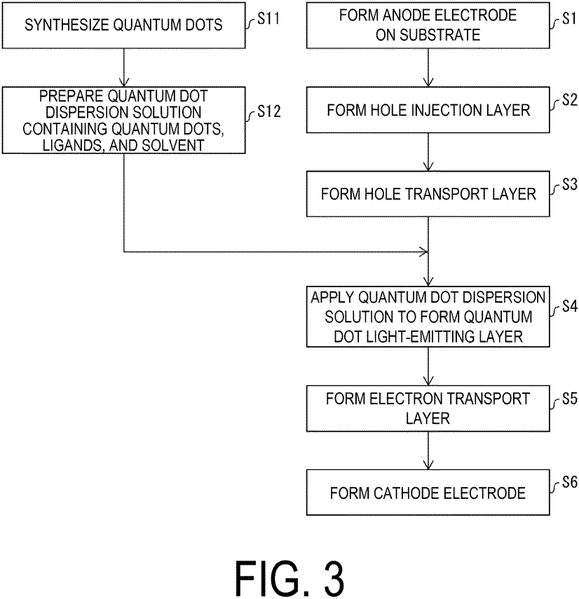

FIG. 3 is a flowchart illustrating an example of a method for manufacturing the electroluminescent element 1 according to the present embodiment.

As illustrated in FIG. 3, in the method for manufacturing the electroluminescent element 1 according to the present embodiment, as one example, for example, first, the anode electrode 12 is formed by sputtering on the substrate 11 (anode electrode formation process, step S1). Next, a solution containing, for example, PEDOT:PSS is applied to the anode electrode 12 by spin coating, after which the solvent is volatilized by baking to form the hole injection layer 13 (hole injection layer formation process, step S2). Next, a solution containing, for example, TFB is applied to the hole injection layer 13 by spin coating, after which the solvent is volatilized by baking to form the hole transport layer 14 (hole transport layer formation process, step S3). Next, the QD layer 15 is formed on the hole transport layer 14 using a solution method. Specifically, the QD dispersion solution 20 in which the QD phosphor particles 25 and ligands 21 are dispersed in the solvent 27 is applied onto the hole transport layer 14 by spin coating. Subsequently, the QD layer 15 is formed by volatilizing the solvent 27 through baking (quantum dot light-emitting layer formation process, step S4). Next, the QD layer 15 is coated with a colloidal solution containing, for example, nanoparticles of ZnO through spin coating, after which the solvent is volatilized by baking, and thereby the electron transport layer 16 is formed (electron transport layer formation process, step S5). Next, the cathode electrode 17 is formed on the electron transport layer 16 by vacuum vapor deposition (cathode electrode formation process, step S6). Note that after formation of the cathode electrode 17 in step S6, the substrate 11 and a layered body (from the anode electrode 12 to the cathode electrode 17) formed on the substrate 11 may be sealed with a sealing member in an N₂ atmosphere.

Furthermore, the QD dispersion solution 20 used in step S4 is prepared (manufactured) in advance prior to implementing step S4. Thus, as illustrated in FIG. 3, the method for manufacturing the electroluminescent element 1 further includes a quantum dot synthesis process (step S11) and a quantum dot dispersion solution preparation process (step S12, quantum dot dispersion solution manufacturing process) before step S4.

In step S11, the QD phosphor particles 25 (quantum dots) used in the QD dispersion solution 20 are synthesized. Specifically, in step S11, a copper chalcogenide is synthesized as a precursor from an organic or inorganic copper compound and an organic chalcogen compound, and the copper chalcogenide is then used to synthesize the QD phosphor particles 25.

In step S12, the QD phosphor particles 25 synthesized in step S11 are used to prepare the QD dispersion solution 20 used in step S4. Specifically, in step S12, the QD phosphor particles 25 synthesized in step S11 and the ligands 21 are dispersed in the solvent 27 at the predetermined concentration described above. Through this, the QD dispersion solution 20 used in step S4 is prepared.

In step S4, as described above, the solvent 27 is volatilized after the QD dispersion solution 20 has been applied. Through this, the QD layer 15 containing the QD phosphor particles 25 and ligands 21 included in the QD dispersion solution 20 is formed. Note that the quantum dot synthesis process (also referred to as the QD phosphor particle synthesis process) of step S11 and the quantum dot dispersion solution preparation process of step S12 are described later in greater detail.

### Quantum Dot Synthesis Process (Step S11)

Next, an example of a method for synthesizing the QD phosphor particles 25 will be described as an example of step S11.

In the present embodiment, a copper chalcogenide is synthesized as the precursor from a Cu raw material (an organic copper compound or an inorganic copper compound) and an organic chalcogen compound as a Se raw material or a Te raw material. Preferable examples of the copper chalcogenide (precursor) include Cu₂Se, Cu₂SeS, Cu₂SeTe, and Cu₂SeTeS.

The organic copper compound (organic copper reagent) used as the Cu raw material is not particularly limited, and examples thereof include acetates and fatty acid salts. Furthermore, the inorganic copper compound (inorganic copper reagent) used as the Cu raw material is also not particularly limited, and examples thereof include halides (copper halides).

More specifically, examples of the acetates include copper (I) acetate (Cu(OAc)) and copper (II) acetate (Cu(OAc)₂).

Examples of the fatty acid salts include copper stearate (Cu(OC(═O)C₁₇H₃₅)₂), copper oleate (Cu(OC(═O)C₁₇H₃₃)₂), copper myristate (Cu(OC(═O)C₁₃H₂₇)₂), copper dodecanoate (Cu(OC(=O)C₁₁H₂₃)₂), and copper acetylacetonate (Cu(acac)₂).

Both monovalent and divalent compounds can be used as the halide. Examples of the halide include copper(I) chloride (CuCl), copper(II) chloride (CuCl₂), copper(I) bromide (CuBr), copper(II) bromide (CuBr₂), copper(I) iodide (CuI), and copper(II) iodide (CuI₂).

In the present embodiment, an organic selenium compound (organic chalcogen compound) is used as the Se raw material. The organic selenium compound (organic chalcogen compound) is not particularly limited, and for example, trioctylphosphine selenide ((C₈H₁₇)₃P=Se) obtained by dissolving Se in trioctylphosphine, and tributylphosphine selenide ((C₄H₉)₃P=Se) obtained by dissolving Se in tributylphosphine can be used. Also, other examples of the organic selenium compound (organic chalcogen compound) that can be used include a solution (Se—ODE) in which Se is dissolved at a high temperature in a high boiling point solvent, which is a long chain hydrocarbon such as octadecene, and a solution (Se-DDT/OLAm) in which Se is dissolved in a mixture of oleylamine and dodecanethiol.

In the present embodiment, an organic tellurium compound (organic chalcogen compound) is used as the Te raw material. The organic tellurium compound (organic chalcogen compound) is not particularly limited, and for example, trioctylphosphine telluride ((C₈H₁₇)₃P=Te) obtained by dissolving Te in trioctylphosphine, and tributylphosphine telluride ((C₄H₉)₃P=Te) obtained by dissolving Te in tributylphosphine can be used. Also, as the organic tellurium compound (organic chalcogen compound), a dialkyl ditelluride (R₂Te₂; where R denotes a C1-C6 alkyl group), such as diphenyl ditelluride ((C₆H₅)₂Te₂) can be used.

In the synthesis of the copper chalcogenide, first, an organic copper compound or an inorganic copper compound, and an organic chalcogen compound are mixed and dissolved in a solvent.

Examples of the solvent include saturated or unsaturated hydrocarbons having a high boiling point. Examples of high boiling point saturated hydrocarbons that can be used include n-dodecane, n-hexadecane, and n-octadecane. An example of a high boiling point unsaturated hydrocarbon that can be used is octadecene. Note that, for example, an aromatic solvent having a high boiling point, and an ester-based solvent having a high boiling point may also be used as the solvent. For example, t-butyl benzene can be used as an aromatic solvent having a high boiling point. Examples of high boiling point ester-based solvents that can be used include butyl butyrate (C₄H₉COOC₄H₉) and benzyl butyrate (C₆H₅CH₂COOC₄H₉). However, aliphatic amine-based compounds, fatty acid-based compounds, aliphatic phosphorus-based compounds, or mixtures thereof can also be used as the solvent.

Next, the reaction temperature is set to within a range from 140° C. to 250° C., and the copper chalcogenide (precursor) is synthesized. Note that the reaction temperature is preferably a lower temperature within a range from 140° C. to 220° C., and more preferably an even lower temperature within a range from 140° C. to 200° C. In this manner, according to the first embodiment, the copper chalcogenide can be synthesized at a low temperature, and therefore the copper chalcogenide can be safely synthesized. In addition, since the reaction during synthesis is gentle, the reaction is easier to control.

Note that in the present embodiment, the reaction method is not particularly limited, but it is important to synthesize Cu₂Se, Cu₂SeS, Cu₂SeTe, and Cu₂SeTeS having uniform particle sizes in order to obtain the QD phosphor particles 25 having a narrow fluorescence full-width at half-maximum.

Also, the particle size of the copper chalcogenide (precursor) such as Cu₂Se, Cu₂SeS, Cu₂SeTe, and Cu₂SeTeS is preferably 20 nm or less, more preferably 15 nm or less, and even more preferably 10 nm or less. Wavelength control of QD phosphor particles 25 such as ZnSe-based, ZnSeS-based, ZnSeTe-based, and ZnSeTeS-based QD phosphor particles is enabled depending on the composition and particle size of this copper chalcogenide. Therefore, it is important to appropriately control the particle size.

It is also important to solid-solve S in the core 25a in order to obtain QD phosphor particles 25 with a narrower fluorescence full-width at half-maximum as the core 25a. For this reason, thiol is preferably added in the synthesis of, for example, Cu₂Se or Cu₂SeTe as the precursor. Also, the above-described Se-DDT/OLAm is more preferably used as the Se raw material in order to obtain the QD phosphor particles 25 having a narrower fluorescence full-width at half-maximum.

While the thiol is not particularly limited, examples of thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Next, an organic zinc compound or an inorganic zinc compound is prepared as a Zn raw material of ZnSe, ZnSeS, ZnSeTe or ZnSeTeS. The organic zinc compound or the inorganic zinc compound is a raw material that is stable even in air and easy to handle. The organic zinc compound or the inorganic zinc compound is not particularly limited, but a zinc compound with high ionic properties is preferably used in order to efficiently carry out a metal exchange reaction. Examples of the organic zinc compound include acetates, nitrates and fatty acid salts. Examples of the inorganic zinc compound include halides (zinc halides).

An example of the acetate that can be used is zinc acetate (Zn(OAc)₂). An example of the nitrate that can be used is zinc nitrate (Zn(NO₃)₂).

More specifically, examples of fatty acid salts that can be used include zinc stearate (Zn(OC(=O)C₁₇H₃₅)₂), zinc oleate (Zn(OC(═O)C₁₇H₃₃)₂), zinc palmitate (Zn(OC(═O)C₁₅H₃₁)₂), zinc myristate (Zn(OC(═O)C₁₃H₂₇)₂), zinc dodecanoate (Zn(OC(═O)C₁₁H₂₃)₂), and zinc acetylacetonate (Zn(acac)₂).

Note that the organic zinc compound may be a zinc carbamate. Examples of zinc carbamates that can be used include zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(=S)N(C₄H₉)₂)₂).

Examples of halides that can be used include zinc chloride (ZnCl₂), zinc bromide (ZnBr₂), and zinc iodide (ZnI₂).

Subsequently, the above-described organic zinc compound or inorganic zinc compound is added to the reaction solution in which the copper chalcogenide (precursor) was synthesized. This results in a metal exchange reaction between Cu of the copper chalcogenide and Zn. The metal exchange reaction is preferably carried out at a temperature from 150° C. to 300° C. Further, the metal exchange reaction is more preferably carried out at a lower temperature in a range from 150° C. to 280°, and is even more preferably carried out at a temperature in a range from 150° C. to 250° C. In this manner, in the present embodiment, the metal exchange reaction can be carried out at a lower temperature, and therefore the safety of the metal exchange reaction can be increased. Furthermore, the metal exchange reaction is more easily controlled.

In the present embodiment, preferably, the metal exchange reaction between Cu and Zn proceeds quantitatively, and the nanocrystals do not contain the Cu of the precursor. This is because when the Cu of the copper chalcogenide remains in the nanocrystals, the Cu serves as a dopant, light is emitted by another light emission mechanism, and the fluorescence full-width at half-maximum could be widened as a result. The residual amount of this Cu is preferably 100 ppm or less, more preferably 50 ppm or less, and ideally 10 ppm or less, in relation to the Zn.

ZnSe-based QD phosphor particles 25 synthesized by a cation exchange method tend to have a higher residual amount of Cu than ZnSe-based QD phosphor particles 25 synthesized by a direct method. However, even though Cu is included in a range from 1 to 10 ppm in relation to Zn, excellent light-emission characteristics can be obtained. Note that the residual amount of Cu enables the determination as to whether the QD phosphor particles 25 is synthesized by the cation exchange method. That is, synthesis by the cation exchange method enables control of the particle size with the copper chalcogenide, and also enables the synthesis of QD phosphor particles 25 that are naturally difficult to react. Therefore, the residual amount of Cu can be used to determine whether the cation exchange method was used.

Also, in the present embodiment, a compound having an auxiliary role of releasing the metal of the copper chalcogenide into the reaction solution by coordination, chelating, or the like is required when metal exchange is carried out.

An example of the compound having the above-described role is a ligand (surface modifier) capable of forming a complex with Cu. Preferable examples of the ligand include phosphine-based (phosphorus-based) ligands, amine-based ligands, and thiol-based (sulfur-based) ligands.

Examples of the phosphine-based ligands include trioctylphosphine (C₈H₁₇)₃P), triphenylphosphine ((C₆H₅)₃P), and tributyl phosphine ((C₄H₉)₃P).

Examples of amine-based ligands include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of thiol-based ligands include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Note that the ligand may be a fatty acid-based ligand or a phosphine oxide-based ligand.

Examples of the fatty acid-based ligands include oleic acid (C₁₇H₃₃COOH), stearic acid (C₁₇H₃₅COOH), palmitic acid (C₁₅H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of the phosphine oxide-based ligands include trioctylphosphine oxide ((C₈H₁₇)₃P=O), triphenylphosphine oxide ((C₆H₅)₃P═O), and tributyl phosphine oxide f ((C₄H₉)₃P═O).

Among these ligands, in consideration of the magnitude of the reaction efficiency, a phosphine-based (phosphorus-based) ligand is more preferable. Through the use of such ligands, the metal exchange between Cu and Zn is appropriately implemented, and QD phosphor particles having a narrow fluorescence full-width at half-maximum and based on Zn and Se can be manufactured. In the present embodiment, the QD phosphor particles 25 can be more easily mass-produced by the above-described cation exchange method than the direct synthesis method.

That is, in the direct synthesis method, for example, an organic zinc compound such as diethylzinc (Et₂Zn) is used to increase the reactivity of Zn raw material. However, diethylzinc is highly reactive and ignites in air, and therefore raw material handling and storage are difficult. For example, the material needs to handle in an inert gas stream. A reaction using diethylzinc also carries risks such as exotherm and ignition, and therefore diethylzinc is not suited for mass production. Likewise, reactions in which, for example, hydrogen selenide (H₂Se) is used to increase the reactivity of the Se raw material are also not suited for mass production from the perspectives of toxicity and safety.

In addition, in reaction systems using a Zn raw material and a Se raw material with high reactivity as described above, ZnSe is produced, but particle production is not controlled, and as a result, the fluorescence full-width at half-maximum of the produced ZnSe becomes wider.

In contrast, as described above, in the present embodiment, the copper chalcogenide is synthesized as the precursor from an organic copper compound or an inorganic copper compound and an organic chalcogen compound. Furthermore, the QD phosphor particles 25 are synthesized by implementing metal exchange using the precursor. Thus, in the present embodiment, the QD phosphor particles 25 are synthesized through the synthesis of the precursor, and the QD phosphor particles 25 are not synthesized directly from the raw materials. According to the present embodiment, through this type of indirect synthesis, it is not necessary to use dangerous reagents that are highly reactive and difficult to handle, and ZnSe-based QD phosphor particles 25 having a narrow fluorescence full-width at half-maximum can be safely and stably synthesized.

Furthermore, in the present embodiment, it is also not always necessary to isolate and purify the precursor. Thus, for example, the desired QD phosphor particles 25 can be obtained by implementing metal exchange between Cu and Zn in one pot. However, the copper chalcogenide, which is the precursor, may also be isolated and purified prior to synthesis of the QD phosphor particles 25, and then used.

The QD phosphor particles 25 synthesized by the above-described technique can exhibit predetermined fluorescence characteristics without the implementation of various treatments such as cleaning, isolation and purification, a covering treatment, and ligand exchange.

However, as described above, the photoluminescence quantum yield can be further increased by covering the core 25a made of a nanocrystal such as ZnSe, ZnSeS, ZnSeTe, or ZnSeTeS, with a shell 25b made of ZnS, ZnSeS, or the like. Furthermore, adopting the core-shell structure allows the fluorescence lifetime to be shortened in comparison to prior to covering with a shell.

In addition, as described above, in comparison to a case of the core 25a alone, the fluorescent peak wavelength can be shortened or lengthened by adopting a core-shell structure.

Also, by adding, to the core 25a made of nanocrystals such as ZnSe, ZnSeS, ZnSeTe, or ZnSeTeS obtained by the cation exchange method, the same raw materials of ZnSe, ZnSeS, ZnSeTe, or ZnSeTeS, a core 25a of QD phosphor particles 25 changed to any particle size while maintaining a uniform particle size can be obtained. Therefore, the wavelength is easily controlled to a range from 410 nm to 470 nm while maintaining the fluorescence full-width at half-maximum at 25 nm or less.

According to the present embodiment, the core-shell structure (core/shell structure) can be formed at the stage of synthesizing the precursor. For example, as the precursor, a precursor (copper chalcogenide) having a core/shell structure of Cu₂Se/Cu₂S can be synthesized by first synthesizing Cu₂Se, and then continuously adding the S raw material. Subsequently, QD phosphor particles 25 having a core/shell structure of ZnSe/ZnS can be synthesized by carrying out metal exchange between Cu and Zn.

In the present embodiment, the S-based material used in the shell 25b is not particularly limited. Examples of the S-based material that can be typically used include thiols.

Examples of the abovementioned thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), octanethiol (C₈H₁₇SH), benzenethiol (C₆H₅SH), a solution (S-TOP) obtained by dissolving sulfur in a high boiling point solvent that is a long-chain phosphine-based hydrocarbon, such as a trioctylphosphine, a solution (S-ODE) obtained by dissolving sulfur in a high boiling point solvent that is a long-chain hydrocarbon such as octadecene, and a solution (S-DDT/OLAm) obtained by dissolving sulfur in a mixture of oleylamine and dodecanethiol.

The reactivity differs depending on the S raw material that is used, and as a result, the covering thickness of the shell 25b (for example, ZnS) can be differed. The thiol system is proportional to the degradation rate thereof, and the reactivity of S-TOP or S-ODE varies in proportion to the stability thereof. Through this, the covering thickness of the shell 25b and the final photoluminescence quantum yield can be controlled by also using a proper S raw material.

In the present embodiment, examples of the Zn raw material that can be used in the core-shell structure include a Zn raw material such as an organic zinc compound or an inorganic zinc compound described above.

Furthermore, with regard to the solvent used during covering with the shell 25b, as the amount of an amine-based solvent is reduced, it becomes easier to form the covering of the shell 25b, and more favorable light-emission characteristics can be obtained. In addition, the light-emission characteristics of the shell 25b after covering differ depending on the ratio of the amine-based solvent and the carboxylic acid-based solvent or phosphine-based solvent.

Moreover, the QD phosphor particles 25 synthesized by the manufacturing method of the present embodiment are aggregated by adding a polar solvent such as toluene, methanol, ethanol, or acetone. The aggregated QD phosphor particles 25 can be separated from unreacted raw materials and collected (in other words, isolated) by implementing centrifugation for example.

### Quantum Dot Dispersion Solution Preparation Process (Step S12)

The QD phosphor particles 25 are protected by the ligands 21 through the quantum dot dispersion solution preparation process of step S12 after the synthesis.

In step S12, the QD phosphor particles 25 that have been separated and collected (isolated) from the unreacted raw materials are dispersed in the solvent 27 (dispersion medium) into which the ligands 21 were added, and thereby the QD dispersion solution 20 is prepared (manufactured).

At this time, as described above, a thiol-based ligand having a thiol group and at least one functional group of ester groups and ether groups is used as the ligand 21. Also, as described above, PGMEA is used as the solvent 27 (dispersion medium).

The QD dispersion solution 20 is prepared such that, as described above, the concentration of the QD phosphor particles 25 in the QD dispersion solution is within a range from 0.2 mg/mL to 100 mg/mL.

According to the present embodiment, the QD layer 15 is produced through the application of the QD dispersion solution 20, and thus a process of diluting the QD dispersion solution 20 when manufacturing the electroluminescent element 1 (or in other words, in a series of processes for manufacturing the electroluminescent element 1) becomes unnecessary, and the takt time is improved.

The light-emission characteristics of the QD phosphor particles 25 and the stability of the light-emission characteristics can be improved by adding the thiol-based ligands 21.

Note that as described above, the QD phosphor particles 25 recovered in step S11 can be re-dispersed in a dispersion medium by adding a dispersion medium. The QD dispersion solution 20 may be prepared by adding a solvent that becomes the ligands 21 to a dispersion solution in which the recovered QD phosphor particles 25 are re-dispersed in a dispersion medium.

The change in light-emission characteristics caused by the addition of the ligands 21 differs greatly depending on the presence or absence of a covering operation of the shell 25b. In particular the fluorescence stability of the QD phosphor particles 25 that are covered by the shell 25b can be improved by adding thiol-based ligands 21.

Next, effects of the electroluminescent element 10 according to the present embodiment will be described through examples and comparative examples. However, the electroluminescent element 1 according to the present embodiment is not limited to the following examples.

Note that in the following synthesis examples, as the oleylamine, “Farmin” available from Kao Corporation was used. Also, “Lunac O-V″ available from Kao Corporation was used as the oleic acid. “Thiokalcol 20” available from Kao Corporation was used as the dodecanethiol (DDT). Furthermore, an anhydrous copper acetate available from Wako Pure Chemical Industries, Ltd. was used as the anhydrous copper acetate. An octadecene (ODE) available from Idemitsu Kosan Co., Ltd. was used as the octadecene. A trioctylphosphine available from Hokko Chemical Industry Co., Ltd. was used as the trioctylphosphine. An anhydrous zinc acetate available from Kishida Chemical Co., Ltd. was used as the anhydrous zinc acetate.

### Example 1

A 300 mL reaction vessel was charged with 543 mg of anhydrous copper acetate (Cu(OAc)₂) as a Cu raw material (organic copper compound), 28.5 mL of oleylamine (OLAm) as a ligand, and 46.5 mL of octadecene (ODE) as a solvent. The raw materials in the reaction vessel were then heated and dissolved at 150° C. for 20 minutes in an inert gas (N₂) atmosphere while being stirred, and a solution was thereby obtained.

Next, 8.4 mL of a Se-DDT/OLAm solution (0.285 M) was added as an organic chalcogen compound to the solution, and the resulting mixture was heated at 150° C. for 10 minutes while being stirred. The reaction solution (Cu₂Se reaction liquid, copper chalcogenide) thereby obtained was cooled to room temperature.

Subsequently, 4.092 g of anhydrous zinc acetate (Zn(OAc)₂) as an organic zinc compound, 60 mL of trioctylphosphine (TOP) as a solvent, and 2.4 mL of oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. Next, 72 mL of octadecene (ODE) was added as a solvent (dispersion medium) to the recovered precipitate, and the precipitate was dispersed, and thereby a ZnSe—ODE dispersion solution was obtained.

Subsequently, 4.092 g of anhydrous zinc acetate (Zn(OAc)₂) as an organic zinc compound, 30 mL of trioctylphosphine (TOP) as a solvent (dispersion medium), and 3 mL of oleylamine (OLAm) and 36 mL of oleic acid as ligands were added to 72 mL of this ZnSe-ODE dispersion solution, and the mixture was heated at 280° C. for 30 minutes in an inert gas (N₂) atmosphere while being stirred. The resulting reaction solution (ZnSe dispersion solution) was cooled to room temperature.

Next, 47 mL of the reaction solution (ZnSe dispersion solution) was collected, ethanol was added thereto to generate a precipitate, and the mixture was centrifuged to recover the precipitate. Next, 35 mL of octadecene (ODE) as a solvent (dispersion medium) was added to the recovered precipitate to thereby disperse the precipitate, and a ZnSe—ODE dispersion solution was obtained.

Subsequently, 35 mL of the ZnSe—ODE dispersion solution was heated at 310° C. for 20 minutes in an inert gas (N₂) atmosphere while being stirred.

Next, a mixed solution of 2.2 mL of an S-TOP solution (2.2 M) as an S raw material and 11 mL of a zinc oleate (Zn(OLAc)₂) solution (0.8 M) as an organic zinc compound was prepared, 1.1 mL of the mixed solution was added to the ZnSe—ODE dispersion solution, and the mixture was heated at 310° C. for 20 minutes while being stirred, and thereby, ZnSe as a core was covered with ZnS as a shell. In the present synthesis example, this operation (covering with a shell) was repeated eight times.

Subsequently, ethanol of a 3-fold amount in relation to this reaction solution (ZnSe/ZnS dispersion solution) was added to the reaction solution to generate a precipitate, the resulting solution was centrifuged, and QD phosphor particles formed from the ZnSe/ZnS precipitate were recovered.

Next, in order to carry out a ligand-exchange process, a 2-fold amount of ligands and a 10-fold amount of ethanol in relation to the solid weight of the obtained QD phosphor particles were added, and the mixture was stirred until the solid component was completely dispersed. Note that thiol-based ligands represented by structural formula (3) (in other words, SH(CH₂)₁₀COO(CH₂CH₂O)₃CH₃) were used as the ligands. As a result, the ligands coordinating to the QD phosphor particles were replaced with the thiol-based ligands represented by structural formula (3).

Subsequently, a 5-fold amount of hexane in relation to the ethanol was added, the mixture was centrifuged, and the ligand-exchanged QD phosphor particles were collected and then dispersed in PGMEA to obtain a QD dispersion solution according to the present embodiment.

Also, the particle size (outermost particle size) of QD phosphor particles (ZnSe/ZnS) in the QD dispersion solution was measured and found to be 10.1 nm. This particle size was calculated as an average value of observed samples in particle observation using a scanning electron microscope (SEM). Note that the SU9000 scanning electron microscope available from Hitachi, Ltd. was used as the scanning electron microscope.

Also, in order to further clarify the effects, the above-described QD dispersion solution was excessively diluted to approximately 0.2 mg/mL, which is a weaker concentration than the concentration of a QD dispersion solution ordinarily used in the manufacture of electroluminescent elements, and the change over time in the photoluminescence quantum yield (PLQY) of the QD dispersion solution was measured. Note that the C9920-02G absolute quantum yield spectrometer available from Hamamatsu Photonics K.K. was used to measure the photoluminescence quantum yield (PLQY).

### Comparative Example 1

A comparative QD dispersion solution was prepared by carrying out the same reactions and operations as in Example 1 with the exception that trioctylphosphine (TOP) was used as the ligand in place of the thiol-based ligand represented by structural formula (3), and hexane was used in place of PGMEA.

In addition, similar to Example 1, the comparative QD dispersion solution was diluted to approximately 0.2 mg/mL, and the change over time of the photoluminescence quantum yield (PLQY) of the QD dispersion solution was measured by the same method as in Example 1.

### Comparative Example 2

A comparative QD dispersion solution was prepared by carrying out the same reactions and operations as in Example 1 with the exception that oleic acid was used as the ligand in place of the thiol-based ligand represented by structural formula (3).

Table 1 shows results of a comparison of the change over time in the photoluminescence quantum yield (PLQY) of the QD dispersion solution obtained in Example 1 and the comparative QD dispersion solution obtained in Comparative Example 1.

TABLE 1

| | | Example 1 | Comparative Example 1 |
|---|---|---|---|
| PLQY (%) | Immediately after dilution | 71.5 | 81.3 |
| | 1 day after dilution | Not measured | 27.7 |
| | 3 days after dilution | 68.3 | Not measured |

As is understood from Table 1, in Comparative Example 1, the PLQY decreased significantly from 81.3% to 27.7% after the passage of only one day after dilution. However, in Example 1, even after the passage of three days following dilution, the PLQY changed from 71.5% to 68.3%, and thus almost no change in the PLQY occurred.

From this, it is clear that when the electroluminescent element 1 is produced according to the present embodiment, almost no decrease in the PLQY occurs even, for example, after three days after diluting the QD dispersion solution 20 to a desired concentration at which a QD layer 15 of a desired layer thickness can be obtained, and thus the electroluminescent element 1 can be used as is.

Therefore, according to the present embodiment, it is not necessary to dilute the QD dispersion solution immediately before forming the QD layer 15, and by using a QD dispersion solution 20 that has been stored in a state of being diluted to a desired concentration in advance, the process of diluting the QD dispersion solution 20 when manufacturing the electroluminescent element 1 becomes unnecessary. Thus, the takt time when manufacturing the electroluminescent element 1 can be improved by using the QD dispersion solution 20 described above.

Note that with the QD dispersion solution of Comparative Example 2, the QD phosphor particles 25 to which oleic acid was coordinated as ligands aggregated in the PGMEA and did not disperse. Therefore, a QD layer 15 in which the QD phosphor particles 25 were uniformly dispersed could not be produced with the QD dispersion solution of Comparative Example 2, and it was found that an electroluminescent element having good element characteristics could not be produced.

### Modified Example

In the description above, A BE-type electroluminescent element 1 was described. However, the electroluminescent element 1 according to the present embodiment is not limited thereto. As described above, the electroluminescent element 1 may be a top-emitting (TE) type electroluminescent element. Note that an example of a TE type electroluminescent element is presented in a third embodiment described below.

In a case where the electroluminescent element 1 is of the TE-type, the LB is emitted from the QD layer 15 in the upward direction of FIG. 1. Thus, a light-reflective electrode is used for the anode electrode 12, and a light-transmissive electrode is used for the cathode electrode 17. A substrate having low translucency (e.g., a plastic substrate) may be used as the substrate 11.

In the TE-type electroluminescent element 1, there are fewer members such as TFTs, for example, that obstruct the path of the LB on the LB light-emitting surface side (emission direction) than in the BE-type electroluminescent element 1. As a result, since the aperture ratio is large, the EQE can be further improved.

### Second Embodiment

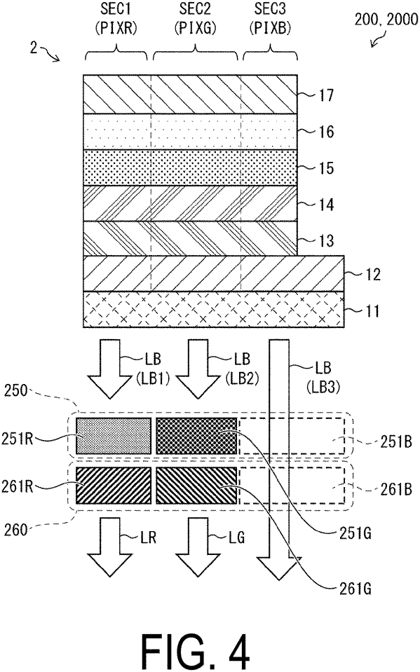

FIG. 4 is a cross-sectional view schematically illustrating an overall configuration of main portions of a display device 2000 according to the present embodiment. The display device 2000 includes a light-emitting device 200. The light-emitting device 200 includes an electroluminescent element 2, a wavelength conversion sheet 250 (wavelength conversion member), and a color filter (CF) sheet 260 (CF member). The light-emitting device 200 may be used as, for example, a backlight for the display device 2000. The light-emitting device 200 configures one picture element including an R pixel (PIXR), a G pixel (PIXG), and a B pixel (PIXB) in the display device 2000.

The display device 2000 includes an R pixel (PIXR), a G pixel (PIXG), and a B pixel (PIXB). Note that the R pixel may be referred to as an R subpixel. This similarly applies to the G pixel and the B pixel.

The electroluminescent element 2 is a BE-type electroluminescent element similar to the electroluminescent element 1. Thus, in the example illustrated in FIG. 4, a display portion (not illustrated) (e.g., a display panel) of the display device 2000 is provided below the electroluminescent element 2.

In the electroluminescent element 2, the QD layer 15 (and each corresponding layer) is partitioned into three subregions (SEC1 to SEC3) in the horizontal direction. More specifically, in the electroluminescent element 2, a plurality of TFTs (not illustrated) are provided in each of the SEC1 to SEC3 so that individual voltages can be applied to the QD layer 15. Accordingly, the light emission state of the QD layer 15 can be individually controlled in each of the SEC1 to SEC3.

The LBs that are emitted from the SEC1 to SEC3 are also referred to below as LB1 to LB3, respectively. In the example of FIG. 4, the SEC1 is set to the PIXR, the SEC2 is set to the PIXG, and the SEC3 is set to the PIXB as the respective corresponding subregions.

The wavelength conversion sheet 250 is provided below the electroluminescent element 2 at positions corresponding to the SEC1 to SEC3. The wavelength conversion sheet 250 converts a wavelength of a portion of the LB (LB1 and LB2) emitted from the QD layer 15. The wavelength conversion sheet 250 includes a red wavelength conversion layer 251R (red wavelength conversion member) and a green wavelength conversion layer 251G (green wavelength conversion member). The wavelength conversion sheet 250 further includes a blue light transmission layer 251B.

The red wavelength conversion layer 251R is provided at a position corresponding to the SEC1. In other words, the PIXR includes the red wavelength conversion layer 251R. The red wavelength conversion layer 251R includes red QD phosphor particles (not illustrated) that emit red light (LR) as fluorescence by receiving the LB1 as excitation light. In other words, the red wavelength conversion layer 251R converts the LB1 into the LR. The red wavelength conversion layer 251R may be referred to as a red quantum dot light-emitting layer.

As described above, unlike the QD layer 15, the red wavelength conversion layer 251R emits light by photoluminescence (PL). The amount of light of the LR can be changed by adjusting the amount of light of the LB1, which is the excitation light. This similarly applies to the green wavelength conversion layer 251G described below. In the SEC1, the LR passing through the red CF 261R is emitted toward the display portion.

The green wavelength conversion layer 251G is provided at a position corresponding to the SEC2. In other words, the PIXG includes the green wavelength conversion layer 251G. The green wavelength conversion layer 251G includes green QD phosphor particles (not illustrated) that emit green light (LG) as fluorescence by receiving the LB2 as excitation light. In other words, the green wavelength conversion layer 251G converts the LB2 into the LG. The green wavelength conversion layer 251G may be referred to as a green quantum dot light-emitting layer. In the SEC2, the LG passing through the green CF 261G is emitted toward the display portion.

The blue light transmission layer 251B is provided at a position corresponding to the SEC3. The blue light transmission layer 251B transmits the LB3. The material of the blue light transmission layer 251B is not particularly limited. The material is preferably a material having a particularly high light transmittance in at least the blue wavelength band (e.g., a glass or a resin having translucency). According to the above configuration, in the SEC3, the LB3 transmitted through the blue light transmission layer 251B is emitted toward the display portion.

In the present embodiment, a blue light transmission layer (hereinafter, a blue light transmission layer 261B) similar to that of the blue light transmission layer 251B is also provided in the CF sheet 260. The blue light transmission layer 261B is also provided at a position corresponding to the SEC3. The material of the blue light transmission layer 261B may be the same as or different from the material of the blue light transmission layer 251B. In the present embodiment, the LB3 transmitted through the blue light transmission layer 251B further passes through the blue light transmission layer 261B and is directed toward the display portion.

Note that the blue light transmission layer 261B of the CF sheet 260 may be provided with a blue CF. Alternatively, in a case where the CF sheet 260 is not provided, the blue CF may be provided in the blue light transmission layer 251B of the wavelength conversion sheet 250.

As described above, according to the light-emitting device 200, light in which the LR, the LG, and the LB3 are mixed (mixed light) can be supplied to the display portion. Accordingly, by appropriately adjusting each of the amounts of light of the LR, the LG, and the LB3, the desired tinge can be represented by the above-described mixed light.

The materials of the red QD phosphor particles and the green QD phosphor particles can be freely selected. As described above, as an example, InP is suitably used as the non-Cd-based material. When InP is used, the fluorescence full-width at half-maximum can be made relatively narrow, and high luminous efficiency can be obtained.

As described in the first embodiment, by using the QD layer 15 as the blue light source, the half width of the blue light and the fluorescent peak wavelength can be controlled precisely compared with before. In other words, the monochromaticity of the blue light (LB3) in the PIXB can be improved. In view of this, in the light-emitting device 200, the wavelength conversion sheet 250 (more specifically, the red wavelength conversion layer 251R and the green wavelength conversion layer 251G) is provided as a red light source and a green light source.

According to the red wavelength conversion layer 251R, the monochromaticity of the red light (LR) in the PIXR can be improved. Similarly, according to the green wavelength conversion layer 251G, the monochromaticity of the green light (LG) in the PIXG can be improved. Thus, according to the light-emitting device 200, the display device 2000 having excellent display quality (color reproducibility, in particular) can be realized.

However, the wavelength conversion sheet 250 cannot necessarily convert all of the LB (LB1 and LB2) received in the SEC1 and the SEC2 into light of a different wavelength. Specifically, the red wavelength conversion layer 251R cannot necessarily convert all of the LB 1 into the LR. In other words, part of the LB1 is not absorbed in the red wavelength conversion layer 251R and passes through the red wavelength conversion layer 251R. Similarly, part of the LB2 is not absorbed in the green wavelength conversion layer 251G and passes through the green wavelength conversion layer 251G. Hereinafter, the LB1 passing through the red wavelength conversion layer 251R is referred to as a first residual blue light. The LB2 passing through the green wavelength conversion layer 251G is referred to as a second residual blue light.

Thus, in order to reduce the effect of the LB passing through the wavelength conversion sheet 250 in the SEC1 and SEC2 (the first residual blue light and the second residual blue light), the CF sheet 260 is provided at a position corresponding to the wavelength conversion sheet 250. The CF sheet 260 is provided below the wavelength conversion sheet 250. In other words, the CF sheet 260 is provided so as to cover the wavelength conversion sheet 250 when viewed from the display surface. The CF sheet 260 includes a red CF 261R and a green CF 261G. As described above, the CF sheet 260 further includes a blue light transmission layer 261B.

In order to reduce the effect of the first residual blue light in the PIXR, the red CF 261R is provided at a position corresponding to the SEC1 (a position corresponding to the red wavelength conversion layer 251R). Similarly, in order to reduce the effect of the second residual blue light in the PIXG, the green CF 261G is provided at a position corresponding to the SEC2 (a position corresponding to the green wavelength conversion layer 251G).

The red CF 261R and the green CF 261G selectively transmit red light and green light, respectively. Specifically, the red CF 261R has a high light transmittance in the red wavelength band and a relatively low light transmittance in other wavelength bands. The green CF 261G has a high light transmittance in the green wavelength band and a relatively low light transmittance in other wavelength bands. In the second embodiment, it is preferable that both of the red CF 261R and the green CF 261G have a particularly low light transmittance in the blue wavelength band.

By providing the CF sheet 260, the first residual blue light directed toward the display portion can be blocked by the red CF 261R. Similarly, the second residual blue light directed toward the display portion can be blocked by the green CF 261G. As a result, the monochromaticity of each of the LR and the LG in the display portion can be further improved. Thus, the display quality of the display device 2000 can be further enhanced. However, depending on the display quality required for the display device 2000, the CF sheet 260 can be omitted.

The wavelength conversion sheet 250 and the CF sheet 260 may be formed integrally. For example, by forming the CF sheet 260 on the upper face of the wavelength conversion sheet 250 at the positions corresponding to the SEC1 to SEC3, an integral sheet (hereinafter, referred to as a “wavelength conversion/CF sheet”) may be manufactured. The wavelength conversion/CF sheet may be disposed below the electroluminescent element 2 such that the CF sheet 260 side of the wavelength conversion/CF sheet faces the display surface.

As another example, by forming the wavelength conversion sheet 250 on the upper face of the CF sheet 260 at the positions corresponding to the SEC1 to SEC3, the wavelength conversion/CF sheet may be manufactured.

As yet another example, the wavelength conversion/CF sheet may be manufactured by forming the red wavelength conversion layer 251R and the green wavelength conversion layer 251G on the upper face of the CF sheet 260 at the respective positions corresponding to the SEC1 and SEC2. As described above, the wavelength conversion sheet may be provided only at positions corresponding to the SEC1 and the SEC2. In this case, the formation of the blue light transmission layer 251B can be omitted.

### Supplement

If the film thickness of the wavelength conversion sheet 250 (more specifically, the film thickness of each of the red wavelength conversion layer 251R and the green wavelength conversion layer 251G; hereinafter, “Dt”) is too small (e.g., less than 0.1 µm), the absorption of the LB in the wavelength conversion sheet 250 is insufficient. As a result, the wavelength conversion efficiency of the wavelength conversion sheet 250 decreases. On the other hand, when the Dt is too large (e.g., when the Dt exceeds 100 µm), the light extraction efficiency in the wavelength conversion sheet 250 decreases. The decrease in the light extraction efficiency is due to, for example, the fluorescence (LR and LG) generated in the wavelength conversion sheet 250 being scattered by the wavelength conversion sheet 250 itself.

As described above, from the perspective of improving the efficiency of the light-emitting device 200, the Dt is preferably 0.1 µm to 100 µm. In order to further improve the efficiency, the Dt is particularly preferably 5 µm to 50 µm. As an example, the Dt can be set to a desired value by forming the wavelength conversion sheet 250 by using a binder.

The material of the binder can be freely selected, but an acrylic resin is preferably used as the material. This is because the acrylic resin has high transparency and can effectively disperse the QDs.

### Modified Example

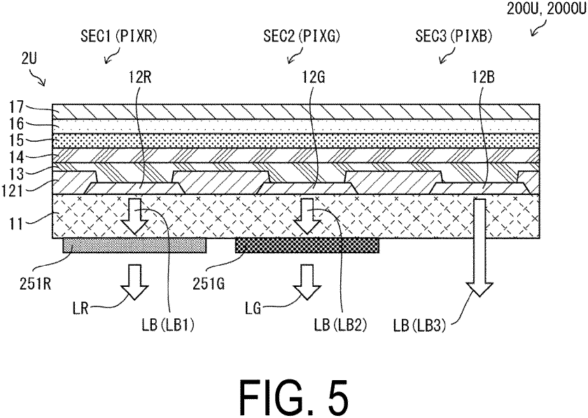

FIG. 5 is a diagram illustrating one modified example of the display device 2000 (hereinafter, a display device 2000U). The light-emitting device and the electroluminescent element of the display device 2000U are referred to as a light-emitting device 200U and an electroluminescent element 2U, respectively. In FIG. 5, for simplicity of illustration, some of the members illustrated in FIG. 4 are not omitted.

In the display device 2000U, a first electrode (e.g., an anode electrode) is provided individually for the PIXR, the PIXG, and the PIXB. Hereinafter, (i) a first electrode provided on the PIXR is referred to as a red first electrode 12R, (ii) a first electrode provided on the PIXG is referred to as a green first electrode 12G, and (iii) a first electrode provided on the PIXB is referred to as a blue first electrode 12B. In the example illustrated in FIG. 5, an edge cover 121 is provided at each end portion of the red first electrode 12R, the green first electrode 12G, and the blue first electrode 12B.

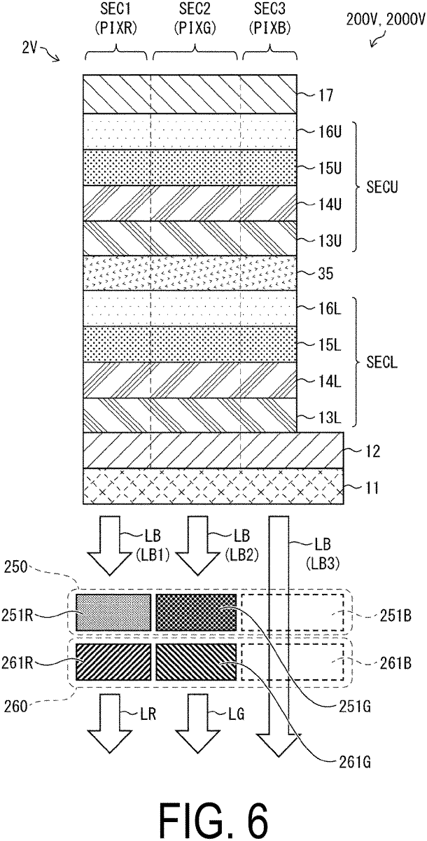

In the display device 2000U, the QD layer 15 is interposed between (i) the red first electrode 12R, the green first electrode 12G, and the blue first electrode 12B and (ii) the cathode electrode 17 (a second electrode). Additionally, the QD layer 15 is shared by the PIXR, the PIXG, and the PIXB. The cathode electrode 17 (the second electrode) is also shared by the PIXR, the PIXG, and the PIXB. This similarly applies to other layers. The display device 2000U can be said to be one specific example of the configuration of the display device 2000. The configuration illustrated in FIG. 5 is also applicable to the configurations of FIG. 6 to FIG. 8 described below.

### Modified Example

FIG. 6 is a diagram illustrating another modified example of the display device 2000 (hereinafter, the display device 2000V). The light-emitting device and the electroluminescent element of the display device 2000V are referred to as a light-emitting device 200V and an electroluminescent element 2V, respectively. The electroluminescent element 2V is a tandem-type electroluminescent element configured based on the electroluminescent element 2.

Specifically, unlike the electroluminescent element 2, the electroluminescent element 2V includes a lower light-emitting unit (SECL) and an upper light-emitting unit (SECU) as a pair of light-emitting units. The SECL is formed on an upper face of the anode electrode 12. On the other hand, the SECU is formed on a lower face of the cathode electrode 17. Each of the SECL and the SECU includes layers similar to the hole injection layer 13 to the electron transport layer 16 of the electroluminescent element 2. In the example illustrated in FIG. 6, the layers of the SECL are referred to as a hole injection layer 13L to an electron transport layer 16L, and the layers of the SECU are referred to as a hole injection layer 13U to an electron transport layer 16U. Also, in the electroluminescent element 2V, a charge generating layer 35 is further provided between the SECL and the SECU.

An example of a method for manufacturing the electroluminescent element 2V is as follows. First, after film formation of the anode electrode 12, the SECL (the hole injection layer 13L to the electron transport layer 16L) is formed on the upper face of the anode electrode 12 by similar techniques as those in the first embodiment. Then, the charge generating layer 35 is formed on the upper face of the electron transport layer 16L. Subsequently, the SECU (the hole injection layer 13U to the electron transport layer 16U) is formed on the upper face of the charge generating layer 35. Finally, the cathode electrode 17 is formed on the upper face of the electron transport layer 16U.

In the electroluminescent element 2V, two QD layers (QD layers 15L and 15U) are provided as blue light sources. Thus, according to the electroluminescent element 2V, the amount of light of the LB can be increased as compared with the electroluminescent element 2. Thus, the amounts of light of the LR and the LG can also be increased as compared with those of the electroluminescent element 2.

As described above, according to the electroluminescent element 2V, the light emission intensity of the light-emitting device 200V can be increased as compared with the light-emitting device 200. Thus, the viewability of the image displayed on the display device 2000V can be increased as compared with the display device 2000. In other words, the display device 2000V having more excellent display quality can be realized.

The charge generating layer 35 of the electroluminescent element 2V is provided as a buffer layer between the electron transport layer 16L and the hole injection layer 13U. By providing the charge generating layer 35, the efficiency of recombination of the positive holes and the electrons in the QD layers 15L and 15U can be improved. In other words, the amount of light of the LB can be increased more effectively. However, depending on the display quality required for the display device 2000V, the charge generating layer 35 can be omitted.

### Third Embodiment

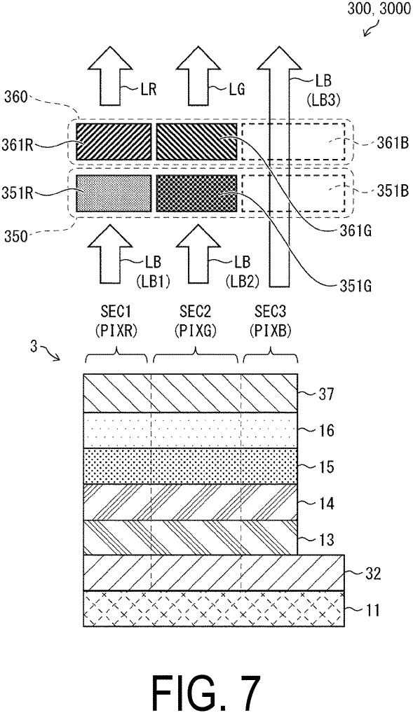

FIG. 7 is a diagram illustrating a display device 3000 according to a third embodiment. The light-emitting device and the electroluminescent element of the display device 3000 are referred to as a light-emitting device 300 and an electroluminescent element 3, respectively. The electroluminescent element 3 has a configuration generally similar to that of the electroluminescent element 2. However, unlike the electroluminescent element 2, the electroluminescent element 3 is the TE-type electroluminescent element. In the example illustrated in FIG. 7, a display portion (not illustrated) of the display device 3000 is provided above the electroluminescent element 3.

Specifically, unlike the anode electrode 12, the anode electrode (hereinafter, the anode electrode 32) (the first electrode) of the electroluminescent element 3 is formed as a light-reflective electrode (an electrode similar to the cathode electrode 17). In contrast, unlike the cathode electrode 17, the cathode electrode (hereinafter, the cathode electrode 37) (the second electrode) of the electroluminescent element 3 is formed as a light-transmissive electrode (an electrode similar to the anode electrode 12). By providing the anode electrode 32 and the cathode electrode 37 in this way, the electroluminescent element 3 of the TE-type can be configured. In the electroluminescent element 3, a substrate having low light-transmittance (e.g., a plastic substrate) can be used as the substrate 11.

A wavelength conversion sheet 350 and a CF sheet 360 illustrated in FIG. 7 are a wavelength conversion sheet and a CF sheet, respectively, of the light-emitting device 300. A red wavelength conversion layer 351R is a red wavelength conversion layer of the wavelength conversion sheet 350, and a green wavelength conversion layer 351G is a green wavelength conversion layer of the wavelength conversion sheet 350. A blue light transmission layer 351B is a blue light transmission layer of the wavelength conversion sheet 350. A red CF 361R is a red CF of the CF sheet 360, and a green CF 361G is a green CF of the CF sheet 360. A blue light transmission layer 361B is a blue light transmission layer of the CF sheet 360.

In the light-emitting device 300, since the electroluminescent element 3 is the TE-type, the wavelength conversion sheet 350 and the CF sheet 360 are disposed above the electroluminescent element 3. The third embodiment also provides similar effects to those of the second embodiment. In addition, as described above, according to the electroluminescent element 3, the EQE can be improved as compared with the electroluminescent element 2 (the BE-type electroluminescent element).

### Modified Example

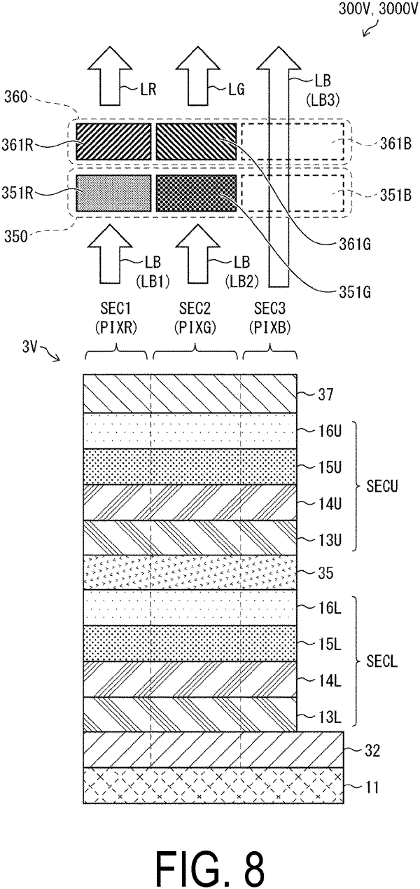

FIG. 8 is a diagram illustrating one modified example of the display device 3000 (hereinafter, the display device 3000V). The light-emitting device and the electroluminescent element of the display device 3000V are referred to as a light-emitting device 300V and an electroluminescent element 3V, respectively. The electroluminescent element 3V is a tandem-type electroluminescent element configured based on the electroluminescent element 3. In this manner, the tandem structure can also be adopted in a TE-type electroluminescent element in a similar manner to that of the example illustrated in FIG. 6 (the electroluminescent element 2V).

Note that in the display device described above, by using the non-Cd-based material for the red QD phosphor particles (the red quantum dots), the green QD phosphor particles (the green quantum dots), and the blue QD phosphor particles (the blue quantum dots), an effect of being possible to provide an environment-friendly display device is exerted.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

1. A quantum dot dispersion solution comprising:
quantum dots;
ligands; and
a solvent,
wherein each ligand includes a thiol group and at least one functional group of ester groups and ether groups, and
the solvent is propylene glycol monomethyl ether acetate.

2. The quantum dot dispersion solution according to claim 1, wherein the ligand is a compound represented by general formula (1): 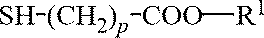
where R¹ denotes a —[(CH₂)_{q}O]ᵣ—R² group that may include a substituent, p denotes an integer from 1 to 15, q denotes an integer from 1 to 5, r denotes an integer from 1 to 15, and R² denotes a hydrogen atom or a C₁-₆ alkyl group.

3. The quantum dot dispersion solution according to claim 1,
wherein the ligand is a compound represented by general formula (2): 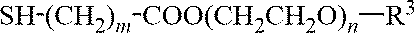
where m denotes an integer from 5 to 11, n denotes an integer from 1 to 10, and R³ denotes a C₁₋₆ alkyl group.

4. The quantum dot dispersion solution according to claim 1,
wherein the ligand is a compound represented by structural formula (23): 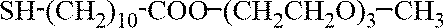
.

5. The quantum dot dispersion solution according to claim 1,
wherein a weight ratio of the ligands to the quantum dots is from 0.01 times to 2 times.

6. The quantum dot dispersion solution according to claim 1,
wherein a concentration of the quantum dots in the quantum dot dispersion solution is within a range from 0.2 mg/mL to 100 mg/mL.

7. The quantum dot dispersion solution according to claim 1,
wherein the quantum dots are Cd-free quantum dots including at least Zn and Se and not including Cd at a mass ratio of 1/30 or higher in relation to Zn, and
a particle size of each quantum dot is within a range from 3 nm to 20 nm.

8. A method for manufacturing an electroluminescent element including a quantum dot light-emitting layer including quantum dots, the method comprising:
applying a quantum dot dispersion solution including quantum dots, ligands, and a solvent to form the quantum dot light-emitting layer,
wherein the quantum dot dispersion solution described in claim 1 is used as the quantum dot dispersion solution in the formation of the quantum dot light-emitting layer.

9. The method for manufacturing an electroluminescent element according to claim 8, the method further comprising:
manufacturing the quantum dot dispersion solution,
wherein the manufacturing the quantum dot dispersion solution includes synthesizing the quantum dots, and
the synthesizing the quantum dots includes synthesizing a copper chalcogenide precursor from an organic or inorganic copper compound and an organic chalcogen compound, and
subjecting the Cu of the copper chalcogenide precursor and Zn to a metal exchange reaction to thereby synthesize the quantum dots.

10. The method for manufacturing an electroluminescent element according to claim 9,
wherein in the metal exchange reaction, metal exchange is carried out at a temperature in a range from 150° C. to 300° C.

11. The method for manufacturing an electroluminescent element according to claim 9,
wherein in the synthesis of the copper chalcogenide precursor, the copper chalcogenide precursor is synthesized at a reaction temperature from 140° C. to 250° C.
